(19) United States
(12) Patent Application Publication
(10) Pub. No.: US 2009/0218941 A1
(43) Pub. Date: Sep. 3, 2009

(54) ORGANIC SEMICONDUCTOR LIGHT-EMITTING DEVICE AND DISPLAY DEVICE

(75) Inventors: Kenji Nakamura, Saitama (JP); Hiroyuki Endo, Tokyo (JP); Atsushi Oda, Yamagata (JP)

Correspondence Address: SUGHRUE MION, PLLC, 2100 PENNSYLVANIA AVENUE, N.W., SUITE 800, WASHINGTON, DC, 20037, US

(73) Assignees: PIONEER CORPORATION, Meguro-ku, Tokyo (JP); NEC CORPORATION, Minato-ku, Tokyo (JP)

(21) Appl. No.: 11/816,597

(22) PCT Filed: Feb. 17, 2006
(86) PCT No.: PCT/JP2006/303344

§ 371 Date: Nov. 8, 2007

(30) Foreign Application Priority Data
Feb. 23, 2005 (JP) 2005-047489

(51) Int. Cl. H05B 33/22; H01L 51/52

(52) U.S. Cl. 313/506; 257/40; 257/79; 257/E51.022

(57) ABSTRACT

A light-emitting element includes a light-emitting material layer having a light-emitting layer; an insulating layer opposed to the light-emitting material layer; a carrier injection layer for injecting a first carrier, sandwiched between the insulating layer and the light-emitting material layer; a first electrode that has a polarity corresponding to the first carrier, positioned at the interface of the light-emitting material layer and the carrier injection layer, and provided in part on the carrier injection layer, a second electrode that has a polarity opposite that of the first electrode and is provided on the light-emitting material layer, and an auxiliary electrode provided on the insulating layer.

### BACKGROUND OF THE INVENTION

1. Field of the Invention

The present invention relates to a light-emitting element using an organic semiconductor and to a display device, and more particularly to an organic semiconductor light-emitting element comprising an auxiliary electrode and to a display device.

2. Description of the Related Art

Organic electroluminescence elements (also referred to hereinbelow as “organic EL elements”) are the elements of a self-luminous type, have a variety of advantages such as a very high response speed and a high luminance, and have been actively researched and developed.

Light-emitting displays composed of such organic EL elements arranged as a matrix have attracted attention and have been widely developed as display devices with a wide view angle, small thickness, and low power consumption.

The conventional organic light-emitting elements represented by the organic EL elements basically are active elements having diode characteristics, and practically all the display devices that have been commercially produced are based on a passive matrix drive. With the passive matrix drive method, an instantly high luminance is necessary to conduct a line sequential drive, and a high-resolution display device is difficult to obtain due a limitation placed on the number of scan lines.

Furthermore, organic EL display devices using thin-film transistors (TFT) formed from polysilicon or the like have been studied in recent years. However, the drawbacks associated with such devices include a high process temperature, a high production cost per unit surface area which is unfavorable factor for large screen size. Furthermore, two or more transistors (switching elements) and at least one capacitor have to be arranged in one pixel to provide for active drive. Therefore, when an active drive display is configured by using organic EL elements, the pixel aperture ratio is decreased due to the aforementioned necessity to arrange the switching elements and capacitor. As a result, power consumption necessary to obtain a sufficient luminance increases. Yet another problem is that the emission life of the organic EL elements becomes short. Other drawbacks include a complex production process and a high manufacturing cost.

Elements with a structure comprising an auxiliary electrode for applying an assist voltage for increasing the amount of carriers injected into a light-emitting material layer have been suggested to increase the emission intensity in organic EL elements (for example, see Japanese Patent Application Kokai No. 2002-343578). However, as the screen size and resolution of display devices are currently rapidly increasing, a strong demand is also created for further reduction in cost, decrease in power consumption, and extension of life of organic EL display devices.

### SUMMARY OF THE INVENTION

The above-described problems are an example of problems to be resolved by the present invention. With the foregoing in view, it is an object of the present invention to provide an organic semiconductor light-emitting element demonstrating excellent performance such as a high light-emission luminance, low power consumption and long service life and suitable for large-screen high-resolution display devices. Another object is to provide a display device demonstrating excellent performance such as a high light-emission luminance, low power consumption and long service life.

The organic semiconductor light-emitting element in accordance with the present invention comprises: a light-emitting material layer having a light-emitting layer; an insulating layer opposed to the light-emitting material layer; a carrier injection layer for injecting a first carrier, sandwiched between the insulating layer and the light-emitting material layer; a first electrode that has a polarity corresponding to the first carrier, positioned at the interface of the light-emitting material layer and the carrier injection layer, and provided in part on the carrier injection layer; a second electrode that has a polarity opposite that of the first electrode and is provided on the light-emitting material layer; and an auxiliary electrode provided on the insulating layer.

The display device in accordance with the present invention comprises a plurality of scan lines, a plurality of drive lines, and a plurality of light-emitting bodies arranged in the intersection positions of the plurality of scan lines and the plurality of drive lines, each light-emitting body being connected to one of the plurality of scan lines and one of the plurality of drive lines, wherein each of the plurality of light-emitting bodies comprises a switching element for transmitting a data signal from one of the plurality of drive lines correspondingly to a signal from one of a plurality of scan lines and an organic semiconductor light-emitting element, and wherein the organic semiconductor light-emitting element comprises: a light-emitting material layer comprising a light-emitting layer; an insulating layer opposed to the light-emitting material layer; a carrier injection layer for injecting a first carrier, sandwiched between the insulating layer and the light-emitting material layer; a first electrode with a polarity corresponding to the first carrier, positioned at the interface of the light-emitting material layer and the carrier injection layer, and provided in part on the carrier injection layer; a second electrode that has a polarity opposite that of the first electrode and is provided on the light-emitting material layer; and an auxiliary electrode receiving a data signal from the switching element, provided on the insulating layer.

### BRIEF DESCRIPTION OF THE DRAWINGS

FIG. 1 is a plan view illustrating schematically the configuration of a light-emitting body comprising an organic EL element of the first embodiment of the present invention;

FIG. 2 is a perspective cross-sectional view illustrating schematically the organic EL element shown in FIG. 1;

FIGS. 3A-3E are cross-sectional views illustrating schematically the process for forming the organic EL element of the first embodiment;

FIG. 4 is a top view illustrating schematically an EL element for the case when an anode and a cathode have a spatially overlapping portion (hatched portion);

FIG. 5 is a plot representing the relationship between an electric current I (μA) between the anode and the cathode, an electric current Ig (nA) between the auxiliary electrode and the cathode, and a voltage applied between the anode and the cathode;

FIG. 6 is a plot representing the relationship between the light emission luminance of the organic EL element and a voltage V (Volt) applied between the anode and the cathode;

FIG. 7 is a perspective cross-sectional view illustrating schematically the configuration of an organic EL element of the second embodiment of the present invention that has a leak current preventing layer;

FIG. 8 is a modification example of the second embodiment shown in FIG. 7; this figure is a perspective cross-sectional view illustrating schematically the configuration of an organic EL element that has a leak current preventing layer on the top surface of the anode;

FIG. 9 is a perspective cross-sectional view illustrating schematically the configuration of the organic EL element of the third embodiment of the present invention;

FIG. 10 is a perspective cross-sectional view illustrating schematically the configuration of the organic EL element of the fourth embodiment of the present invention;

FIG. 11 is a block diagram illustrating schematically the configuration of the display device of the fifth embodiment of the present invention; and

FIG. 12 is an equivalent circuit diagram illustrating the configuration of one light-emitting body in the display device shown in FIG. 11.

### DETAILED DESCRIPTION OF THE INVENTION

Embodiments of the present invention will be described below in more detail with reference to the appended drawings. In the embodiments described below, the equivalent structural elements will be assigned with identical reference numerals.

### First Embodiment

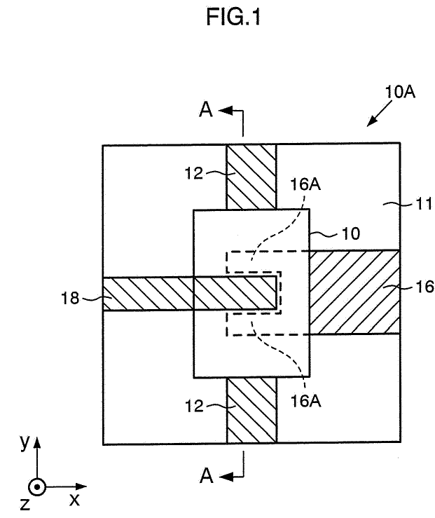

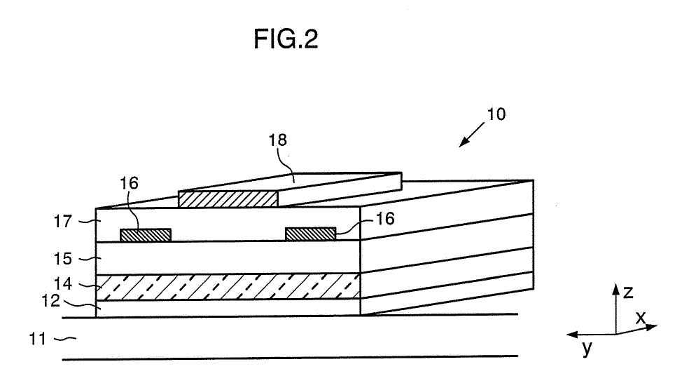

FIG. 1 is a plan view illustrating schematically the configuration of a light-emitting body 10A comprising an organic EL element 10 that is the first embodiment of the present invention. FIG. 2 is a perspective cross-sectional view illustrating schematically the organic EL element 10 shown in FIG. 1. Thus, the cross-section relating to line A-A of the organic EL element 10 shown in FIG. 1 is shown in FIG. 2. To simplify the drawings, hatching is provided only with respect to the cross-section relating to line A-A of the organic EL element 10.

The light-emitting body 10A is composed as a unit light-emitting body for configuring a display device. Thus, a display device can be configured by arranging a plurality of light-emitting bodies 10A in the form of a matrix or other shape.

The organic EL element 10, which is the light-emitting element of the light-emitting body 10A, is formed on a substrate 11. More specifically, an auxiliary electrode 12, an insulating layer 14, and a hole injection layer 15 are formed in this order on the substrate 11. Then, a light-emitting layer 17 is formed on the hole injection layer 15, and an anode 16 is formed at the interface of the hole injection layer 15 and the light-emitting layer 17. The anode 16 is embedded in the light-emitting layer 17 and is formed to be in contact with the hole injection layer 15. Thus, the anode 16 is formed in part on the hole injection layer 15 by patterning, and the hole injection layer 15 is formed so as to be in contact with the light-emitting layer 17 outside the formation region of the anode 16.

As will be described below, a hole transport layer and the like may be also provided, in addition to the light-emitting layer 17, between the hole injection layer 15 and the light-emitting layer 17. A stacked layer comprising the light-emitting layer 17 and the auxiliary layers (for example, a hole transport layer) that are provided above and/ors below the light-emitting layer 17 for assisting the light emission of the light-emitting layer 17 will be referred to hereinbelow as a light-emitting material layer. When a hole transport layer is provided between the hole injection layer 15 and the light-emitting layer 17, the anode 16 may be formed in part inside the hole transport layer (or light-emitting material layer) that is an interface of the hole transport layer (or light-emitting material layer) and the hole injection layer 15 and may be formed so as to be in contact with the hole injection layer 15.

A cathode 18 is formed on the light-emitting layer 17. More specifically, the cathode 18 has a stripe shape. Furthermore, the anode 16 has two stripe sections 16A parallel to the cathode 18. FIG. 1 illustrates the case where the anode 16 and cathode 18 are formed to have such shapes and to be in such locations that they do not overlap spatially in the direction (z direction in FIG. 1: stacking direction) perpendicular to the plane (xy plane in FIG. 1) where the light-emitting layer 17 was formed. The cathode 18 and anode 16 do not necessarily have a stripe shape.

In the above-described organic EL element 10, some of the holes (first carriers) introduced from the anode (first electrode) 16 flow directly to the light-emitting layer 17, but most of the holes introduced from the anode 16 flow to the light-emitting layer 17 via the hole injection layer 15. The holes that were injected into the light-emitting layer 17 recombine with electrons (second carriers) injected into the light-emitting layer 17 from the cathode (second electrode) 18, thereby producing light emission.

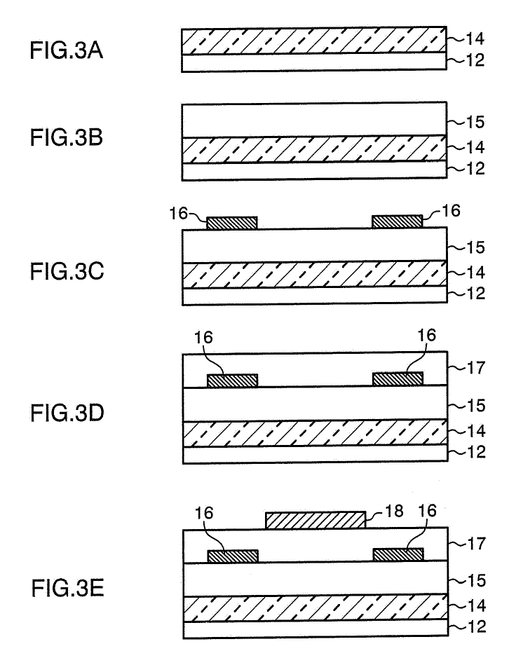

A process of forming the organic EL element 10 of the present embodiment and materials of each structural element will be described below in greater detail with reference to FIGS. 3A to 3E.

### (1) Formation of Auxiliary Electrode and Insulating Layer (FIG. 3A)

First, an auxiliary electrode is formed on the substrate 11 (FIG. 1, FIG. 2). Thus, for example, a film of indium tin oxide (ITO) is formed to a thickness of 100 nm by a sputtering method on an alkali-free glass substrate 11 and then a photoresist is coated with a spin coater. The photoresist is patterned by exposure and development using an optical mask. Then, the ITO film is removed by milling in the portions where the photoresist is absent. Finally, the photoresist is dissolved by using a stripping solution and the photoresist is removed. The auxiliary electrode 12 is formed by this process.

Then, an insulating film is formed to a thickness of 420 nm by a spin coating method by using a propylene glycol monomethyl ether acetate (PGMEA) solution of a polyvinyl phenol polymer (10 wt. %). The polymer film formed in the end sections above the auxiliary electrode 12 is then wiped out, e.g., with cotton impregnated with PGMEA, and the insulating layer 14 is formed by conducting baking for 10 min. (minutes) at a temperature of 200° C. by using a hot plate.

(2) Formation of Hole Injection Layer (FIG. 3b)

A copper phthalocyanine (CuPc) film is formed to a thickness of 50 nm as the hole injection layer 15. In this process, the pentacene film formation rate is 0.1 nm/sec.

(3) Formation of Anode (FIG. 3c)

A gold (Au) film is formed to a thickness of 50 nm as the anode 16 by a vacuum vapor deposition method using a metal mask. The gold film formation rate is 0.2 nm/sec.

(4) Formation of Light-Emitting Layer (FIG. 3d)

A tris(8-quinolinolate) aluminum film is formed to a thickness of 60 nm by a vacuum vapor deposition method as the light-emitting layer 17.

### (5) Formation of Cathode (FIG. 3E)

Magnesium (Mg) and silver (Ag) are co-deposited to a thickness of 100 nm at a ratio of 10:1 by a vacuum vapor deposition method as the cathode 18. At this time, the magnesium (Mg) film formation rate is 1 nm/sec and the silver (Ag) film formation rate is 0.1 nm/sec.

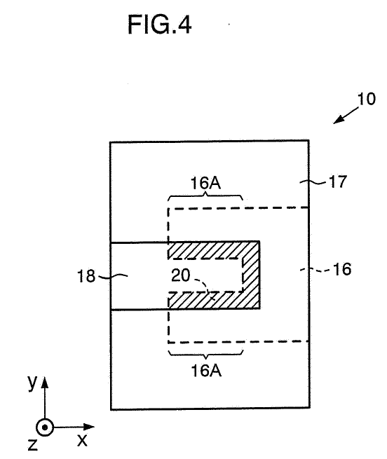

As shown in the top view of the EL element 10 in FIG. 4, vapor deposition of the cathode 18 is conducted by using a metal mask so that the spatial overlapping (hatched portion 20 in FIG. 4) of the sections where the anode 16 and cathode 18 were formed in the direction (z-direction; stacking direction) perpendicular to the plane (xy-plane) where the light-emitting layer 17 was formed is 50% or less of each electrode surface area of the anode 16 and cathode 18 (50% or less of the electrode surface area of the electrode with a smaller surface area). As a result, leak current can be suppressed. Furthermore, it is even more preferred that the anode 16 and cathode 18 be formed to have such shapes and to be in such locations that they do not overlap spatially, as shown in FIG. 1 (that is, the surface area of the hatched portion 20 is zero).

All the above-described steps (2) to (5) are implemented in vacuum.

Furthermore, the hole injection layer 15 can be formed by using a vacuum vapor deposition method or a spin coating method. In the present embodiment, the film forming ability of the hole injection material of a coating type can be improved by forming the anode 16 after the hole injection layer 15 has been formed. Furthermore, not only with a hole injection material of a coating type, but also with a hole injection material formed by vacuum vapor deposition, the electric current flowing in the cathode and light emission intensity can be reduced when no voltage is applied to the anode (OFF state). As a result, the ratio of the current and light emission intensity observed when a voltage is applied to the anode (ON state) to those observed when no voltage is applied (OFF state) is increased.

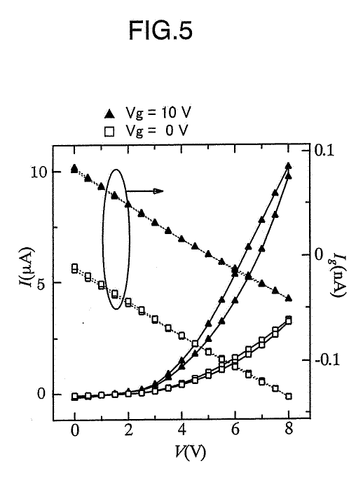

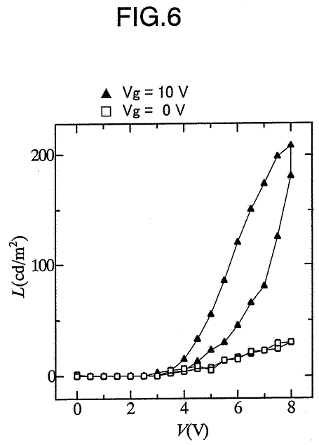

An example of driving the organic EL element 10 of the present embodiment will be described below. FIG. 5 is a plot representing the relationship between an electric current I (μA) between the anode 16 and the cathode 18, an electric current Ig (nA) between the auxiliary electrode 12 and the cathode 18, and a voltage V (Volt) applied between the anode 16 and the cathode 18. FIG. 6 is a plot representing the relationship between the light emission luminance (cd/m²) of the organic EL element 10 and a voltage V (Volt) applied between the anode 16 and the cathode 18.

When no voltage was applied to the auxiliary electrode 12 (Vg=0), an electric current of I=4.2 μA flowed when a voltage of 8 V was applied between the anode 16 and the cathode 18 (FIG. 5). Furthermore, the light emission luminance at this time was about 1.6 cd/m² (FIG. 6). However, when a voltage of 10 V (Vg=10) was applied between the auxiliary electrode 12 and the cathode 18, an electric current of I=100 μA flowed and a light emission luminance of 50 cd/m² was confirmed. At this time, the electric current flowing to the auxiliary electrode 12 was less than 10 nA/cm². Thus, the light emission luminance and the light emission characteristic of the organic EL element 10 were found to be greatly improved by applying a voltage between the auxiliary electrode 12 and the cathode 18.

The reason for the improved operation characteristic attained in the present embodiment will be described below. In the present embodiment, the anode 16 is deposited and patterned after the hole injection layer 15 has been formed. Furthermore, the light-emitting layer 17 is formed on the patterned anode 16, and the anode 16 is formed so as to be in electric contact with the hole injection layer 15. More specifically, the properties of the film at the interface of the anode 16 and the layer formed on the patterned anode 16 are generally inferior to those of the layer formed on a flat surface. In the present embodiment, the anode 16 is formed on a flat hole injection layer 15, and the film properties at the interface between the anode 16 and the hole injection layer 15 are good and favorable. Therefore, holes are effectively injected from the anode 16 into the hole injection layer 15. Furthermore, hole injection from the anode 16 is assisted by the auxiliary electrode 12 and the movement of holes is accelerated by the voltage applied between the auxiliary electrode 12 and the cathode 18, thereby enhancing the flow of electric current to the light-emitting layer 17 of the EL element and increasing the light emission luminance.

Various materials can be used for each above-described layer. This issue will be described below in greater detail.

Examples of materials for the cathode 18, anode 16 and auxiliary electrode 12 used herein include metals such as Ti, Al, Li:Al, Cu, Ni, Ag, Mg:Ag, Au, Pt, Pd, Ir, Cr, Mo, W, Ta, and alloys thereof. Alternatively, electrically conductive polymers such as polyaniline or PEDT:PSS can be used. Furthermore, oxide transparent conductive films, such as films comprising tin-doped indium oxide (ITO), zinc-doped indium oxide (IZO), indium oxide (In₂O₃), zinc oxide (ZnO), or tin oxide (SnO₂) as the main component can be used, but this list is not limiting. Furthermore, the thickness of each electrode is preferably 30-500 nm. A range of 50-300 nm is especially suitable for the thickness of the cathode 18 an auxiliary electrode 12. A range of about 30-200 nm is especially suitable for the thickness of the cathode 16. Furthermore, those electrode materials are preferably fabricated by a vacuum vapor deposition method or sputtering method.

A variety of insulating materials represented by SiO₂ and Si₃N₄ can be used for the insulating layer 14. Inorganic oxide films with a high dielectric constant are especially preferred. Examples of inorganic oxides include silicon oxide, aluminum oxide, tantalum oxide, titanium oxide, tin oxide, vanadium oxide, barium strontium titanate, barium titanate zirconate, lead titanate zirconate, lead lanthanum titanate, strontium titanate, barium titanate, barium magnesium fluoride, bismuth titanate, strontium bismuth titanate, strontium bismuth tantalate, bismuth niobate tantalate, and yttrium trioxide. The preferred among them are silicon oxide, aluminum oxide, tantalum oxide, and titanium oxide. Inorganic nitrides such as silicon nitride and aluminum nitride can be also advantageously used. Examples of suitable organic compound films include films of polyimides, polyamides, polyesters, polyacrylates, photocurable resins of a photoradical polymerization system or a photocation polymerization system, copolymers comprising an acrylonitrile component, polyvinyl phenol, polyvinyl alcohol, novolac resins, cyanoethyl pluran, and phosphazene compounds comprising a polymer structure or an elastomer structure.

The hole injection layer 15 has a function of facilitating the injection of holes from the anode and a function of transporting the holes with good stability. Porphyrin derivatives represented by copper phthalocyanine (CuPc), polymer arylamines called starburst amines represented by m-TDATA, and polyamines represented by pentacene can be effectively used in low-polymer systems. Furthermore, a layer with increased electric conductivity obtained by mixing a Lewis salt or tetrafluoro-tetracyanoquinodimethane (F4-TCNQ) mixing with a porphyrin derivative or triphenylamine derivative can be also used. In this case, the components are preferably mixed at a weight ratio of 5-95%. Furthermore, of the polymer systems, conductive polymer materials such as polyanilines (PANI), polythiophene derivatives (PEDOT), and poly(3-hexylthiophene) (P3HT) can be used. A layer containing a mixture of those materials or a laminate of layers of those materials also may be used for the hole injection layer.

The light-emitting layer 17 comprises a fluorescent substance or a phosphorescent substance, which is a compound having a light-emitting function. At least one compound selected from the compounds disclosed in Japanese Patent Application Laid-open No. 63-264692, such as quinacridone, rubrene, and styryl colorants can be used as such fluorescent substance. Examples of phosphorescent substances include organic indium complexes and organic platinum complexes such as described in Appl. Phys. Lett. Vol. 75, page 4 (1999).

Furthermore, a hole transport layer may be introduced between the hole injection layer 15 and the light-emitting layer 17. Examples of materials suitable for the hole transport layer include triphenyldiamine derivatives, styrylamine derivatives, amine derivatives having an aromatic condensation ring, carbazole derivatives, and polymer materials such as polyvinyl carbazole and derivatives thereof and polythiophene. Those compounds may be used in combinations of two or more thereof. It is generally more preferred that a material with an ionization potential Ip higher than that of the hole injection layer be used.

If necessary, an electron injection and transport layer may be used between the light-emitting layer 17 and the cathode 18. Examples of materials suitable for the electron injection and transport layer include quinoline derivatives such as organometallic complexes having 8-quinolinol or a derivative thereof as a ligand, e.g., tris(8-quinolinolate)aluminum (Alq3), oxadiazole derivatives, perylene derivatives, pyridine derivatives, pyrimidine derivatives, quinoxaline derivatives, diphenylquinone derivatives, and nitro-substituted fluorine derivatives. The electron injection and transport layer may also serve as the light-emitting layer. In this case, tris(8-quinolinolate)aluminum is preferably used. Furthermore, the electron injection layer and electron transport layer can be laminated. In this case, the lamination is preferably conducted in the order of compounds with a larger electron affinity value from the cathode side.

Materials for substrates are not limited to glass, quartz, and semitransparent materials such as plastic materials, e.g., polystyrene, and non-transparent material such as silicon and Al, thermosetting resins such as phenolic resins, and thermoplastic resins such as polycarbonates can be used. Those examples are, however, not limiting and a variety of other materials can be also used.

### Second Embodiment

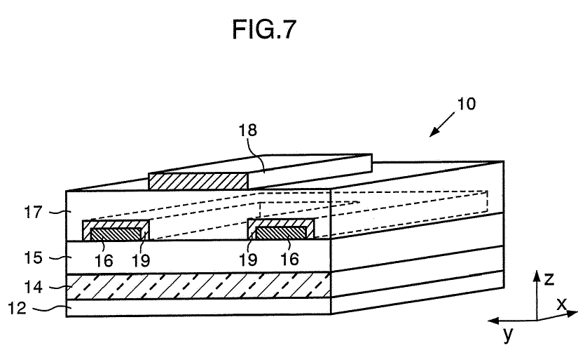

FIG. 7 is a perspective cross-sectional view, similarly to FIG. 2, that illustrates schematically an organic EL element 10 which is the second embodiment of the present invention.

In the present embodiment, in the organic EL element 10, an auxiliary electrode 12, an insulating layer 14, and a hole injection layer 15 are formed successively in this order on a substrate 11 (see FIG. 2). Then a light-emitting layer 17 is formed on the hole injection layer 15, and an anode 16 and an insulating layer 19 are formed at the interface between the hole injection layer 15 and the light-emitting layer 17. Thus, the anode 16 is positioned at the interface of the light-emitting layer 17 and the hole injection layer 15, provided in part above the hole injection layer 15, and formed so as to be in contact with the hole injection layer 15. Furthermore, an insulating layer (leak current preventing layer) 19 for preventing a leak current between the anode 16 and the cathode 18 is provided between the anode 16 and the light-emitting layer 17. In the present embodiment, the leak current preventing layer 19 is formed on the entire surface where the anode 16 and the light-emitting layer 17 are in contact with each other, i.e. so as to surround the anode 16, except the interface of the hole injection layer 15 and the anode 16.

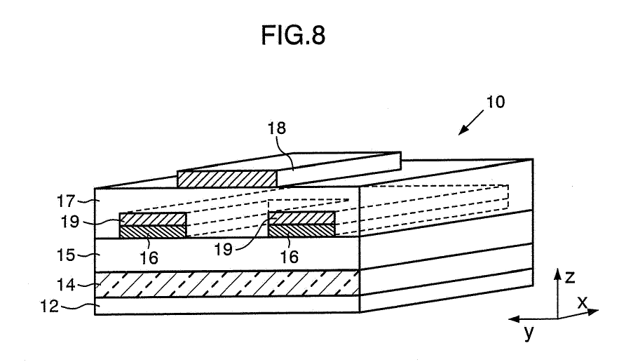

The leak current preventing layer 19 may be provided in part between the anode 16 and the light-emitting layer 17. For example, as shown in FIG. 8, the leak current preventing layer 19 may be provided on the anode 16, except the side surface of the anode 16. Alternatively, the leak current preventing layer 19 may be provided on the anode 16 in the portion where the anode 16 and the cathode 18 spatially overlap. Essentially, the leak current preventing layer 19 may be provided at least in the part between the anode 16 and the light-emitting layer 17 so as to be capable of preventing the leak current form the anode 16 to the cathode 18.

When the above-described leak current preventing layer 19 is provided, the leak current is reduced. Therefore, the anode 16 and the cathode 18 may be formed to have such shapes and to be in such locations that the anode 16 and the cathode 18 overlap spatially in the stacking direction (z-direction in the figure).

In the above-described organic EL element 10, the electric current does not flow from the anode 16 to the cathode 18 directly via the light-emitting layer 17, or even if such a current flows, it is extremely small. Almost all the holes injected from the anode 16 are effectively injected into the light-emitting layer 17 via the hole injection layer 15, to recombine with electrons, and make contribution to light emission. Therefore, the light emission luminance and light emission characteristic of the organic EL element 10 are further greatly improved.

### Third Embodiment

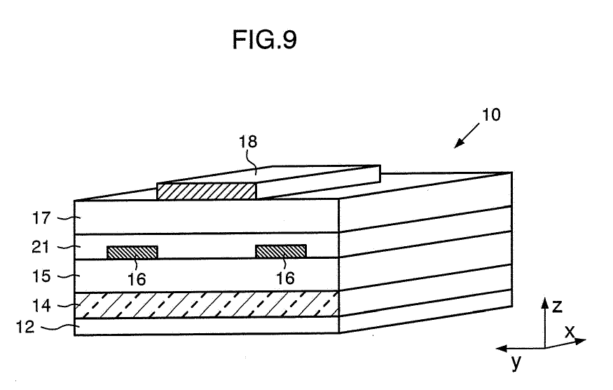

FIG. 9 is a perspective cross-sectional view, similarly to FIG. 2, that illustrates schematically an organic EL element 10 which is the third embodiment of the present invention. The difference between the third embodiment and the above-described embodiments is in that a hole transport layer is provided between a hole injection layer and a light-emitting layer. Thus, the above-described light-emitting material layer comprises a light-emitting layer and a hole transport layer.

More specifically, in the organic EL element 10, an auxiliary electrode 12, an insulating layer 14, and a hole injection layer 15 are formed successively in the order of description on a substrate 11. Then, an anode 16 is patterned and formed on the hole injection layer 15. A hole transport layer 21 is then formed on the hole injection layer 15 so that the anode 16 is embedded therein. Thus, the anode 16 is formed so as to be in contact with the hole injection layer 15 at the interface of the hole injection layer 15 and the hole transport layer 21.

A light-emitting layer 17 is formed on the hole transport layer 21. Furthermore, a cathode 18 having a stripe shape is formed on the light-emitting layer 17. As for the anode 16 and the cathode 18, it is preferred that the anode 16 and the cathode 18 be formed so that spatial overlapping of the portions where the anode 16 and the cathode 18 are formed in the direction (z-direction: stacking direction) perpendicular to a plane (xy-plane) where the light-emitting layer 17 was formed be not more than 50% the surface area of the electrode of the anode 16 and the cathode 18 that has a smaller surface area. Furthermore, it is further preferred that the anode 16 and the cathode 18 be formed to have such shapes and to be in such locations that they do not overlap spatially.

In this embodiment, the holes are also effectively injected from the anode 16 into the hole injection layer 15 via good interface between the abode 16 and the hole injection layer 15. As for the hole injection from the anode 16, due to the assistance of the auxiliary electrode 12, the movement of holes is accelerated by the voltage applied between the auxiliary electrode 12 and the cathode 18, and the light emission luminance can be increased by the hole transport layer 21 providing for hole transport to the light-emitting layer 17.

### Fourth Embodiment

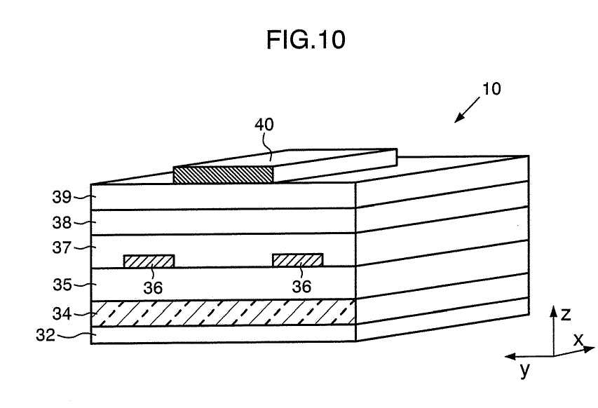

FIG. 10 is a perspective cross-sectional view that, similarly to FIG. 2, illustrates schematically an organic EL element 10 which is the fourth embodiment of the present invention. In the above-described embodiments, an example was explained in which the anode and the light-emitting layer were formed on the hole injection layer, but in the present embodiment, a cathode and a hole injection layer are formed on an electron injection layer.

More specifically, in an organic EL element 10, an auxiliary electrode 32, an insulating layer 34, and an electron injection layer 35 are formed successively in the order of description on a substrate 11. Then, a patterned cathode 36 is formed on the electron injection layer 35. A light-emitting layer 37 is formed on the electron injection layer 35 where the patterned cathode 36 was formed. Thus, the cathode 36 is positioned at the interface of the light-emitting layer 37 and the electron injection layer 35, provided in part on the electron injection layer 35, and formed to be in contact with the electron injection layer 35.

A hole transport layer 38 and a hole injection layer 39 are formed on the light-emitting layer 37. Furthermore, an anode 40 is formed on the hole injection layer 39. More specifically, the anode 40 has a stripe shape.

As for the anode 36 and the cathode 40, it is preferred that the anode 36 and the cathode 40 be formed so that the spatial overlapping of the portions where the anode 36 and the cathode 40 are formed in the direction (z direction: stacking direction) perpendicular to a plane (xy plane) where the light-emitting layer 37 was formed be not more than 50% the surface area of the electrode of the anode 36 and the cathode 40 that has a smaller surface area. Furthermore, it is further preferred that the anode 36 and the cathode 40 be formed to have such shapes and to be in such locations that they do not overlap spatially.

The steps of forming the organic EL element 10 in the present embodiment will be described below in greater detail.

### (1) Formation of Auxiliary Electrode and Insulating Layer

A film of indium tin oxide (ITO) was formed by a sputtering method to a thickness of 100 nm on an alkali-free glass substrate 11. The ITO film was then patterned by photolithography in the same manner as in the first embodiment and the auxiliary electrode 32 was formed.

A SiO₂ film was then formed to a thickness of 300 nm as the insulating film 34 by a sputtering method. The film formation range was restricted by using a metal mask so that the insulating film was not formed in part of the auxiliary electrode.

### (2) Formation of Electron Injection Layer.

A co-deposited film of vasocuproin and cesium was formed as the electron injection layer 35 by vacuum vapor deposition.

### (3) Formation of Cathode

Magnesium (Mg) and silver (Ag) were co-deposited to a thickness of 100 nm at a 10:1 ratio by a vacuum vapor deposition method to obtain the cathode 36. In this process, the magnesium film formation rate was 1 nm/s and the silver film formation rate was 0.1 nm/s.

### (4) Formation of Light-Emitting Layer

Tris(8-quinolinolate)aluminum (Alq3) and Coumarin 6 were co-deposited by a vacuum vapor deposition method to obtain a film with a thickness of 40 nm as the light-emitting layer 37. In this process, the concentration of Coumarin 6 was 3 wt. %. The Alq3 film formation rate was 0.3 nm/s.

### (5) Formation of Hole Transport Layer

A film of a-NPD was formed as a hole transport layer 38 to a thickness of 50 nm by a vacuum vapor deposition method using a metal mask.

### (6) Formation of Hole Injection Layer

A film of CuPc was formed as a hole injection layer 39 to a thickness of 30 nm by a vacuum vapor deposition method using a metal mask.

### (7) Formation of Anode

A film of gold (Au) was deposited as the anode 40 to a thickness of 100 nm by a vacuum vapor deposition method. The gold film formation rate was 1 nm/s. In this case, the film formation range was restricted with a metal mask in the same manner as in the first embodiment.

In the organic EL element 10 fabricated by the above-described process, electrons are also effectively injected from the cathode 36 to the electron injection layer 35 via a good interface between the cathode 36 and the electron injection layer 35. As for the electron injection from the cathode 36, due to the assistance of the auxiliary electrode 12, the movement of electrons is accelerated by the voltage applied between the auxiliary electrode 12 and the anode 40 and the injection of electrons into the light-emitting layer 37 is conducted more effectively, thereby enabling the increase in the light emission luminance.

Furthermore, any one layer of the hole transport layer 38 and the hole injection layer 39 may be formed between the light-emitting layer 37 and the anode 40. Furthermore, in the case of an EL element with a polarity inverted with respect to that of the present embodiment, an electron transport layer or an electron injection layer, or both such layers may be formed. Moreover, an electron transport layer may be formed between the cathode 36 and the light-emitting layer 37.

### Fifth Embodiment

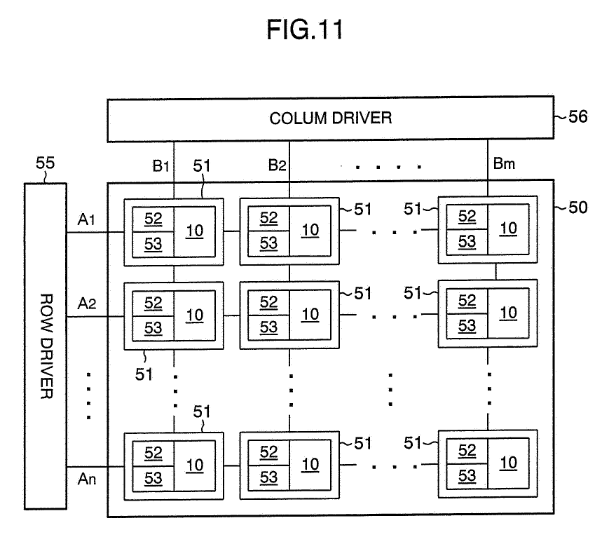

FIG. 11 is a block diagram illustrating schematically the configuration of a display device 50 which is the fifth embodiment of the present invention.

In the display device 50, a plurality of unit light-emitting body 51 comprising the above-described organic EL elements 10 are arranged. As shown in FIG. 11, the unit light-emitting body (also referred to hereinbelow simply as “light-emitting body”) 51 comprises an EL element 10, a switching element 52, and a holding capacitor 53 and constitutes one pixel of the display device 50. The display device 50 is configured by arranging a plurality of light-emitting bodies 51 in a matrix form and configured as an active matrix light-emitting display device.

The display device 50 is connected via scanning lines Ai (i=1−n) to a row driver circuit (also referred to hereinbelow simply as “row driver”) 55 for driving a plurality of light-emitting bodies arranged as a matrix (n rows, m columns). Furthermore, the display device 50 is also connected to a column drive circuit (sometimes referred to hereinbelow simply as “column driver”) 56 with data lines Bj (j=1−m). Due to the operation of the row driver 55 and the column driver 56, the display device 50 can display the input video signals. For example, the drive by the video data signals from the column driver 56 is conducted, while successively scanning each row (scan line) with the row driver 55. The display of inputted images can be performed by conducting such drive operations for each unit frame interval corresponding to the synchronization timing of inputted video signals.

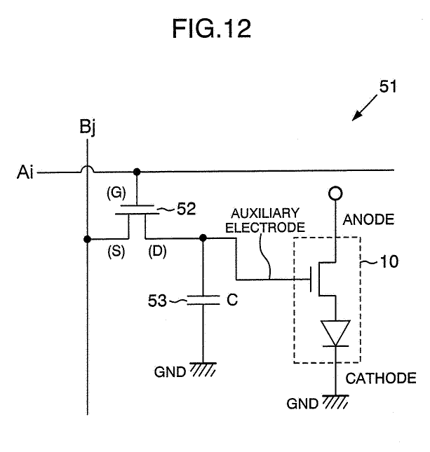

FIG. 12 shows the configuration of the light-emitting body 51. The light-emitting body 51 positioned in the i-th row and the j-th column of the matrix of the display device 50 is described as an example, but other light-emitting bodies 51 have the same configuration. The light-emitting body 51 comprises a switching element (switching transistor) 52, a capacitor 53 for data holding, and the EL element 10. The gate (G) and the source (S) of the switching transistor 52 are connected to the scan line Ai and the data line Bj, respectively. The capacitor 53 for data holding is connected between the drain (D) of the switching transistor 52 and a ground voltage (GND). The connection point of the drain (D) of the switching transistor 52 and the capacitor 53 is connected to the auxiliary electrode of the EL element 10. Furthermore, the anode of the EL element 10 is connected to a power source outputting a voltage for inducing light emission from the EL element 10, and the cathode of the EL element 10 is connected to the ground voltage (GND). FIG. 12 shows an equivalent circuit of the EL element 10.

The operation of the light-emitting body 51 will be described below. If a voltage is applied to the scan line Ai with the row driver 55 and a voltage is applied to the gate (G) of the switching transistor 52, the switching transistor 52 becomes conductive. If a voltage is applied in this state by the column driver 56 to the data line Bj, an electric charge is accumulated and held in the capacitor 53. The voltage held by the capacitor 53 is applied to the auxiliary electrode of the EL element 10 and the EL element 10 emits light according, for example, to the characteristic of the EL element 10 shown in FIG. 6. Conducting such drive operation with respect to each EL element 10 of the drive device 50 correspondingly to the input video signal makes it possible to display the inputted image.

According to the present embodiment, employing the above-described EL element 10 in a display device of an active matrix drive type makes it possible to decrease the number of devices or elements (switching elements) disposed in one pixel. Therefore, the cost can be reduced, power consumption can be decreased, and service life can be extended, for example, in organic EL element display devices using polysilicon or the like.

The above-described embodiments can be appropriately combined. Furthermore, a configuration may be employed comprising EL elements with a polarity inverted with respect to that of the above-described embodiments. In this case, the polarity of electrodes, the injection layers, and the transport layers may be appropriately set according to the corresponding carriers (holes or electrons).

What is claimed is:

1. An organic semiconductor light-emitting element comprising:
a light-emitting material layer comprising a light-emitting layer;
an insulating layer opposed to the light-emitting material layer;
a carrier injection layer for injecting a first carrier, the carrier injection layer sandwiched between the insulating layer and the light-emitting material layer;
a first electrode which has a polarity corresponding to the first carrier, positioned at the interface of the light-emitting material layer and the carrier injection layer, and provided in part on the carrier injection layer;
a second electrode which has a polarity opposite to that of the first electrode and is provided on the light-emitting material layer, and
an auxiliary electrode provided on the insulating layer.

2. The organic semiconductor light-emitting element according to claim 1, having an insulating layer provided between the first electrode and the light-emitting material layer.

3. The organic semiconductor light-emitting element according to claim 1, wherein the carrier injection layer is a hole injection layer, the first electrode is an anode, and the light-emitting material layer comprises a hole transport layer provided between the hole injection layer and the light-emitting layer.

4. The organic semiconductor light-emitting element according to claim 3, wherein the ionization potential of the hole transport layer is larger than the ionization potential of the hole injection layer.

5. The organic semiconductor light-emitting element according to claim 1, wherein the first electrode and the second electrode have a shape such that the first electrode and the second electrode do not overlap spatially in the direction perpendicular to the light-emitting layer.

6. The organic semiconductor light-emitting element according to claim 1, wherein the carrier injection layer is an electron injection layer, the first electrode is a cathode, and the light-emitting material layer comprises an electron transport layer provided between the electron injection layer and the light-emitting layer.

7. The organic semiconductor light-emitting element according to claim 6, wherein en electron affinity of the electron transport layer is smaller than the ionization potential of the electron injection layer.

8. The organic semiconductor light-emitting element according to claim 1, wherein at least one layer of a second carrier injection layer for injecting into the light-emitting layer a second carrier with a polarity opposite that of the carrier injected by the carrier injection layer and a second carrier transport layer for transporting the second carrier is provided between the light-emitting material layer and the second electrode.

9. A display device comprising a plurality of scan lines, a plurality of drive lines, and a plurality of light-emitting bodies arranged at the intersection positions of the plurality of scan lines and the plurality of drive lines, each light-emitting body being connected to one of the plurality of scan lines and one of the plurality of drive lines, wherein
each of the plurality light-emitting bodies comprises:
a switching element for transmitting a data signal from one of the plurality of drive lines correspondingly to a signal from one of a plurality of scan lines; and
an organic semiconductor light-emitting element, and wherein
the organic semiconductor light-emitting element comprises:
a light-emitting material layer comprising a light-emitting layer;
an insulating layer opposed to the light-emitting material layer;
a carrier injection layer for injecting a first carrier, sandwiched between the insulating layer and the light-emitting material layer;
a first electrode with a polarity corresponding to the first carrier, positioned at the interface of the light-emitting material layer and the carrier injection layer, and provided in part on the carrier injection layer;
a second electrode that has a polarity opposite that of the first electrode and is provided on the light-emitting material layer; and
an auxiliary electrode receiving a data signal from the switching element, provided on the insulating layer.

10. The display device according to claim 9, further comprising a capacitor for holding a data signal from the switching element, wherein the auxiliary electrode receives the accumulated voltage of the capacitor.

11. The display device according to claim 9, wherein the organic semiconductor light-emitting element has an insulating layer provided between the first electrode and the light-emitting material layer.
